(19) United States
(12) Patent Application Publication
(10) Pub. No.: US 2015/0201486 A1
(43) Pub. Date: Jul. 16, 2015

(54) Stacked Heatsink Assembly

(71) Applicant: Whelen Engineering Company, Inc., Chester, CT (US)

(72) Inventor: Gregory S. Voelker, East Hampton, CT (US)

(21) Appl. No.: 14/598,823

(22) Filed: Jan. 16, 2015

Related U.S. Application Data
(60) Provisional application No. 61/928,155, filed on Jan. 16, 2014.

(51) Int. Cl. H05K 1/02; H05K 7/20

(52) U.S. Cl. CPC H05K 1/0203; H05K 7/2039; H05K 2201/10106; H05K 2201/10113

(57) ABSTRACT

A stacked heatsink comprises a first thermally conductive plate and a second thermally conductive plate. The first thermally conductive plate defines one or more recesses. The first and second thermally conductive plates each have first and second surfaces. The first thermally conductive plate second surface is configured in thermally conductive contact with the second thermally conductive plate first surface. The one or more recesses are configured to accommodate electronic components mounted to a surface of a printed circuit board to which the heatsink will be secured.

### BACKGROUND OF THE DISCLOSURE

The present disclosure relates to a heatsink assembly, and more particularly, to a heatsink assembly compatible with light emitting diode (hereafter referred to as “LED”) lightheads for mounting to vehicles.

It is traditional to arrange lights on a vehicle to perform a variety of functions, including fog lighting, warning lighting, spot lighting, takedown lighting, scene lighting, ground lighting, and alley lighting. Emergency vehicles such as police, fire, rescue, and ambulance vehicles typically include lights intended to serve several of these functions. Generally speaking, larger lights are less useful than smaller lights because of limited mounting space on the vehicles, as well as aerodynamic and aesthetic considerations. The trend is toward very bright and compact lights which use LEDs for a light source.

The combination of a light source, housing, optics, lens, associated power delivery, and control components will be referred to as a “lighthead.” LED lightheads used with motor vehicles are becoming more compact, which limits the space available for components within the lighthead housing. One of the important functions in an LED lighthead is removal of heat generated by the LEDs. LEDs are heat sensitive in that exposure to high temperatures over extended periods has an adverse impact on the light output and reliability of the LEDs.

Heat sinks are typically employed to provide a thermally conductive path to move heat away from the LEDs. It is common to arrange a planar surface of a heat sink against the planar back side of a printed circuit board (hereafter referred to as “PCB”) where electronic components, including LEDs, are arranged on the opposite front side. The large surface contact area between the heatsink and the PCB provided by such an arrangement facilitates the efficient movement of heat away from the LEDs. Modern electronic manufacturing allows the arrangement of electronic components on both the front and the back of a PCB, permitting a far more compact arrangement and reducing the need for electrical connections between multiple PCBs. However, components mounted to the back side of a PCB interrupt that surface and preclude mounting a planar heat sink flush against the back side of the PCB. One solution is to mold a heat sink from thermally conductive material such that there are voids in the heat sink to accommodate components on the back side of the PCB. The typical material for such heat sinks is die cast metal, but some plastic materials can be used for this purpose. Molded parts require the fabrication of molds and the use of specialized equipment, increasing the cost and extending the lead times for molded heat sinks.

Fabricating metal heatsinks from sheets of aluminum is a popular technique for creating heatsinks, given aluminum's high conductivity and its comparative low cost. Although the flat configuration of traditional sheet metal heatsinks is efficient and manufacture is relatively simple, the flat configuration requires LEDs and other electronic components to be mounted to only one side of the PCB. Increased complexity and smaller size may require electronic components to be mounted to both sides of a PCB. Conventional flat sheet metal heatsinks are not compatible with two-sided PCBs, due to the need to accommodate components mounted on both sides.

Accordingly, there is a need in the market for an inexpensive heat sink compatible with two-sided PCBs.

### SUMMARY

In accordance with various aspects of the current disclosure, a heatsink for diffusing heat created by heat-generating components generally comprises first and second thermally conductive components. The first thermally conductive component defines a plurality of recesses configured to receive components from one side of a two-sided PCB. In one embodiment, the recesses comprise at least one set of pathways. The first and second thermally conductive components each have first and second surfaces. The second thermally conductive component first surface is configured in thermally conductive contact with the first thermally conductive component second surface. The first and second thermally conductive components are stacked to create a heatsink assembly.

In accordance with other aspects of the present disclosure, an LED lighthead for mounting to a vehicle utilizing a sheet metal heatsink assembly includes a PCB having first and second surfaces. A plurality of LEDs are mounted to the first surface of the PCB, while a plurality of other electronic components are mounted to the second surface. The electronic components which are mounted to the second surface are mounted such that they project from the PCB second surface a maximum height “h”.

The heatsink assembly includes first and second thermally conductive plates. The first thermally conductive plate is disposed intermediate the PCB and the second thermally conductive plate. Recesses defined by the first thermally conductive plate are configured to receive the electronic components which are mounted to the second surface of the PCB, thereby permitting the first thermally conductive plate to rest against the PCB second surface. The second thermally conductive plate second surface is exposed to an ambient environment of the lighthead. Other brackets or thermally conductive support surfaces may extend the thermal path carrying heat away from the LEDs.

The disclosed heatsink assembly efficiently conducts heat away from the PCB, and allows for utilization of both first and second surfaces of a PCB. In one embodiment of the present disclosure, the recesses comprise a plurality of orthogonally oriented pathways having a size configured to receive the electronic components which are mounted to the second surface of the PCB.

A heatsink assembly according to aspects of the present disclosure optimizes the usable space within an electronic assembly. By permitting use of both surfaces of a PCB, the heatsink of the present disclosure reduces manufacturing costs, eliminates connections between PCBs, and reduces the overall depth of the assembly.

### BRIEF DESCRIPTION OF THE DRAWINGS

Aspects of the preferred embodiment will be described in reference to the Drawings, where like numerals reflect like elements:

FIG. 1 shows an exploded view of a lighthead of the current disclosure shown from a frontal isometric perspective;

FIG. 2 shows a detailed exploded view of a heatsink assembly of the current disclosure shown from a frontal isometric perspective;

FIG. 3 shows an exploded view of a lighthead of the current disclosure shown from a rear isometric perspective;

FIG. 4 shows a top-plan view of a fully assembled lighthead of the current disclosure with wiring omitted; and

FIG. 5 shows a cross-sectional view of the lighthead of FIG. 4; the cross section is depicted as intersecting the lighthead along axis A-A.

### DETAILED DESCRIPTION OF THE PREFERRED EMBODIMENT

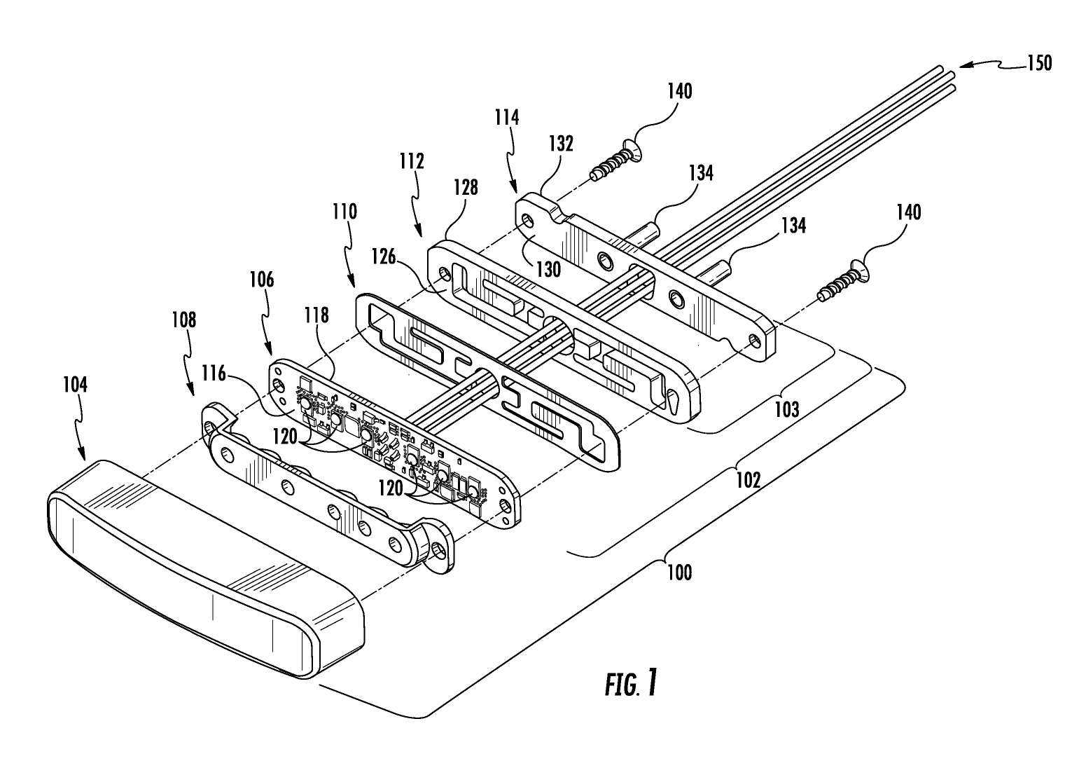

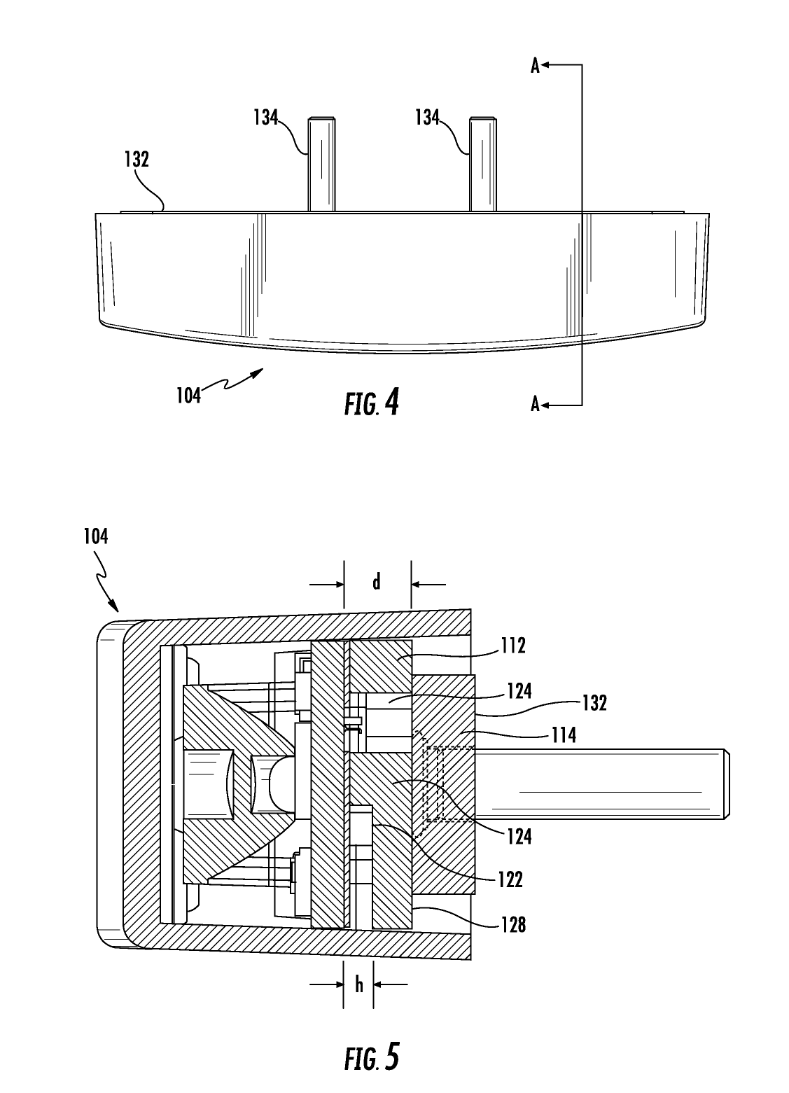

Embodiments of a stacked heatsink of the current disclosure will be discussed with reference to a compact LED lighthead depicted in FIGS. 1-5. Although FIGS. 1-5 depict a stacked sheet metal heatsink assembly as a component of an LED lighthead, one of ordinary skill in the art will appreciate that the heatsink assembly can be used with any number of electronic assemblies and incorporate a variety of thermally conductive materials without departing from the scope of the disclosure.

FIG. 1 depicts a lighthead 100 for attachment to a vehicle (not shown). The lighthead 100 generally comprises a base assembly 102 and a light-transmissive lens 104 attachable to the base assembly 102. As shown in FIG. 1, a plurality of threaded fasteners 140 attach the light-transmissive lens 104 to the base assembly 102. Other attachment means may also be utilized.

The base assembly 102 includes the stacked heatsink assembly 103 and a PCB 106. The PCB 106 has first and second surfaces, 116 and 118, respectively. A plurality of LEDs 120 are mounted to the first surface 116 of the PC board 106. In the embodiment shown in FIGS. 1 and 3-5, an optional optical lens 108 is mounted to the PCB first surface 116 to provide a desired light emission pattern. While the optical lens 108 depicted in the figures is a total internal reflector (TIR), a variety of optical lenses may be utilized to emit light having a desired pattern and intensity. The embodiments shown in FIGS. 1 and 3-5 also depict a gasket 110, formed of thermally conductive material, intermediate the PCB second surface 118 and the stacked heatsink assembly 103, as a component of base assembly 102

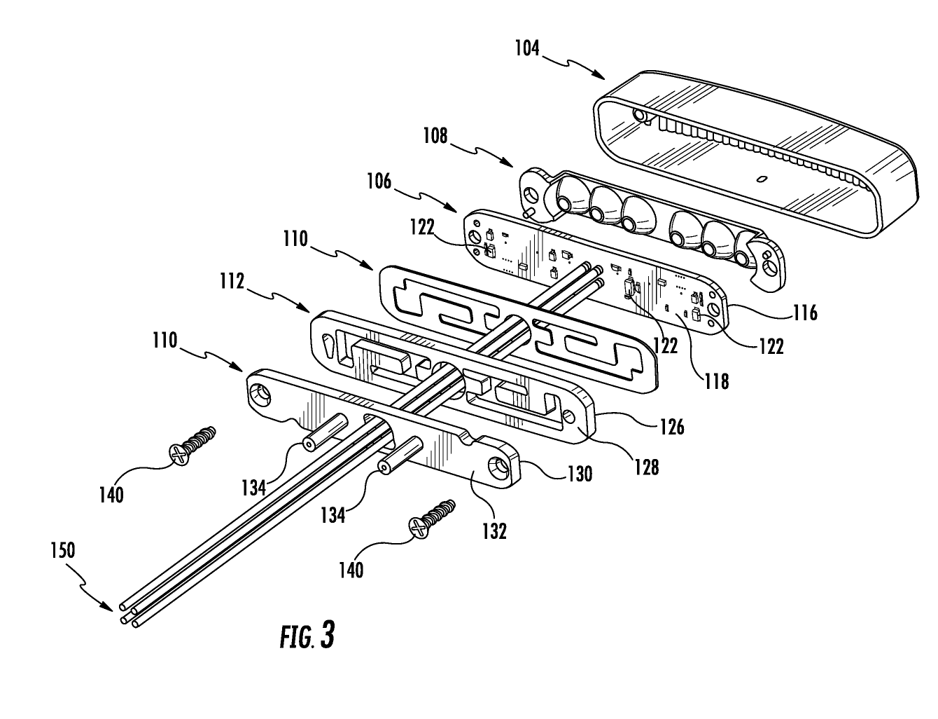

As best seen in FIGS. 3 and 5, a plurality of electronic components 122 are mounted to the PCB second surface 118. The electronic components 122 are mounted such that they project from the PCB second surface 118 a maximum height “h”. The electronic components 122 in this embodiment may include, for example, transistors, capacitors, resistors, or other electronic components necessary for producing light having the desired intensity and light emission pattern.

Referring to FIGS. 1-3, the stacked heatsink assembly 103 includes first and second thermally conductive plates 112 and 114, respectively. The first thermally conductive plate 112 is mounted intermediate the PCB second surface 118 and the second thermally conductive plate 114.

The first thermally conductive plate 114 defines a plurality of recesses 124, which are configured to receive the electronic components 122. In the embodiment shown in the figures, the recesses 124 may comprise a plurality of pathways 125, configured to accommodate the electronic components 122. The pathways 125 may be oriented orthogonally with respect to one another and themselves, and may extend between first and second surfaces 126 and 128, respectively, of the first thermally conductive plate 114. While the embodiment shown in the figures depicts a plurality of recesses 124 forming pathways 125, one of ordinary skill in the art will appreciate that there may be any number of recesses 124, which may be independent or form multiple separate or interconnected pathways without departing from the scope of the disclosure. Additionally, it is understood that the first thermally conductive plate 114 could be formed of one or more layers, each layer not necessarily having the same recesses 124 or pathways 125, depending upon the layout and relative heights of electronic components 122.

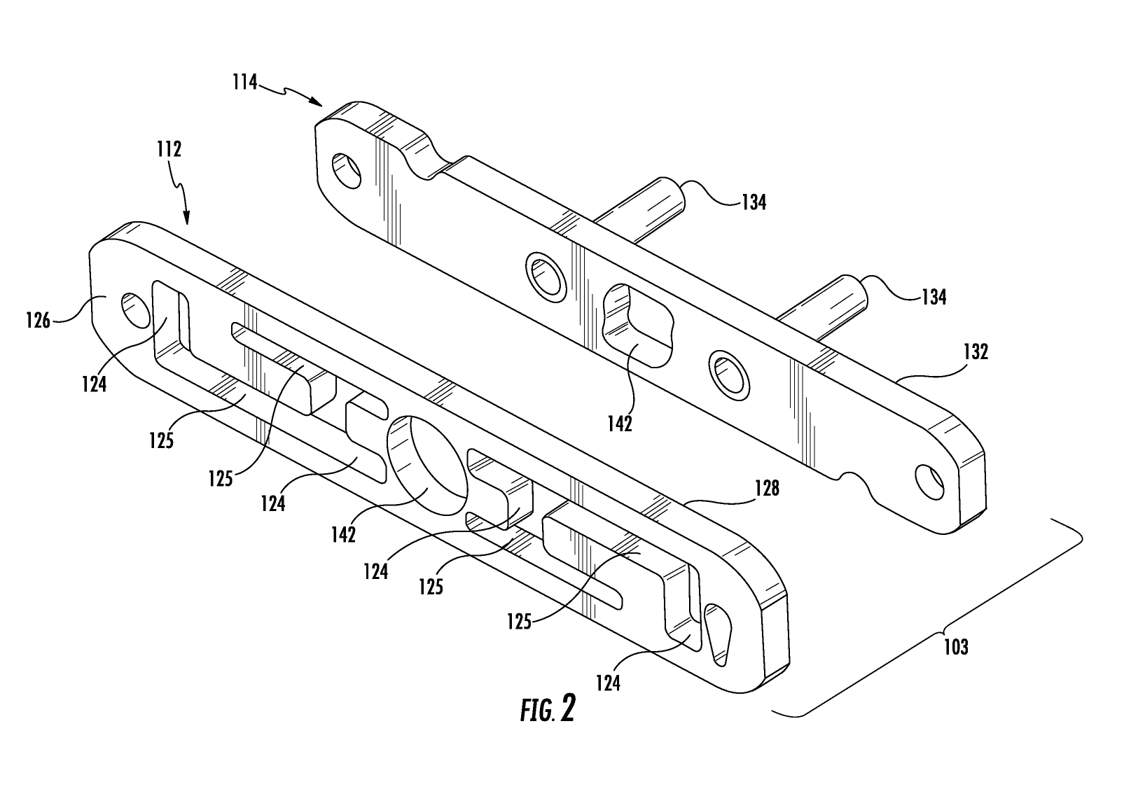

As best seen in FIGS. 2, 3, and 5, the recesses 124 of the first thermally conductive plate 112 receive the electronic components 122 and ensure that no gap is necessary between the PCB second surface 188, the gasket 110, and the first thermally conductive plate first surface 126 to allow for the maximum height “h” of the electronic components 122. A second thermally conductive plate first surface 130 is placed in thermally conductive contact with the first thermally conductive plate second surface 128. The second thermally conductive plate first surface 130 is a distance “d” from the PCB second surface 118. The distance “d” is at least equal to the maximum height “h”. A second thermally conductive plate second surface 132 is exposed to the ambient environment, and configured to conduct heat into the air surrounding the lighthead 100 or into other brackets or conductive support surfaces which may be used to further conduct heat away from the LEDs.

In the embodiment shown in FIGS. 1 and 3-5, the gasket 110 is intermediate the PCB second surface 118 and the first thermally conductive plate first surface 126 and has a thickness which is within the distance “d” between the PCB second surface 118 and the second thermally conductive plate first surface 130. The gasket 110, first thermally conductive plate 112, and second thermally conductive plate 114, may contain pass-throughs 142 for conductors for powering and communication with the PCB 106, such as wiring 150. The gasket 110 may also define recesses and pass-throughs to receive the electronic components 122 and may have other pathways similar to the pathways 125 of the first thermally conductive plate 112. Additionally, as most clearly visualized in FIG. 5, a seal (not shown) may be applied between the first thermally conductive plate 122, the second thermally conductive plate 114, and the light-transmissive lens 104. The seal may also just be applied between the second thermally conductive plate 114 and the light-transmissive lens 104. The seal may be a variety of materials, including an electronics potting compound.

Not only does the configuration of the stacked heatsink assembly 103 allow for utilization of both surfaces of the PCB 106, but it also ensures efficient conduction of heat away from the LEDs 120 and the electronic components 122. Heat generated by the LEDs 120 is transferred to the PCB second surface 118 via holes in the PCB 106 filled with a thermally conductive material, known as vias (not shown) and the gasket 110. Alternatives to vias, such as a conductive metal core within the PCB, may also be used.

The recesses 124 receive the electronic components 122, and the first surface 130 of the second thermally conductive plate 114 is disposed in thermally conductive contact with the first thermally conductive plate 112 and adjacent the electronic components 122. The first and second thermally conductive plates 112 and 114, respectively, thus act in concert to conduct heat away from the PCB 106 and into the environment surrounding the lighthead 100. Referring to FIGS. 1-4, mounting posts 134 are secured to the second thermally conductive plate 114, and act as connectors to mount the lighthead 100 to a surface or bracket (not shown). The mounting posts 134 may be constructed from a thermally conductive material to increase the surface area of the second thermally conductive plate 114 exposed to the ambient environment.

While a preferred embodiment has been set forth for purposes of illustration, the foregoing description should not be deemed a limitation of the invention herein. Accordingly, various modifications, adaptations, and alternatives may occur to one skilled in the art without departing from the spirit of the invention and scope of the claimed coverage.

What is claimed is:

1. A heatsink assembly for diffusing heat created by heat-generating components attached to a circuit board comprising:
a printed circuit board having first and second surfaces;
one or more electronic components having maximum height “h” mounted to said printed circuit board second surface;
a first thermally conductive having first and second surfaces and defining one or more recesses; and
a second thermally conductive plate having first and second surfaces, wherein said first thermally conductive plate second surface is configured in thermally conductive contact with said second thermally conductive plate first surface, said second thermally conductive plate first surface is a distance “d” from said printed circuit board second surface, wherein said distance “d” is at least equal to said maximum height “h”, and said one or more recesses are configured to receive said one or more electronic components.

2. The heatsink assembly of claim 1, wherein said one or more recesses comprise one or more pathways.

3. The heatsink assembly of claim 2, wherein said one or more pathways are orthogonally-oriented with respect to one another.

4. The heatsink assembly of claim 2, wherein said one or more pathways are defined to extend between said first thermally conductive plate first surface and said first thermally conductive second surface.

5. The heatsink assembly of claim 1, wherein said first thermally conductive plate is formed of one or more sheets of sheet metal.

6. The heatsink assembly of claim 1, wherein said second thermally conductive plate is formed of one or more sheets of sheet metal.

7. A heatsink assembly for diffusing heat created by heat-generating components attached to a circuit board comprising:
a printed circuit board having first and second surfaces;
one or more electronic components having a maximum height “h” mounted to said printed circuit board second surface;
a first sheet metal plate having first and second surfaces and defining one or more recesses;
a second sheet metal plate having first and second surfaces;
wherein said first sheet metal plate second surface is in thermal communication with said second sheet metal plate first surface, said second sheet metal plate first surface is a distance “d” from said printed circuit board second surface, said distance “d” is at least equal to said maximum height “h”, said one or more recesses are configured to receive the said one or more electronic components, and said one or more recesses comprise one or more orthogonally oriented pathways.

8. The heatsink assembly of claim 7, wherein one or more gaskets are located intermediate said printed circuit board second surface and said second sheet metal plate first surface.

9. The heatsink assembly of claim 7, wherein said second sheet metal plate second surface has a periphery that is smaller than said first sheet metal plate second surface periphery.

10. The heatsink assembly of claim 7, wherein said printed circuit board is located within a lens enclosure having a rear periphery.

11. The heatsink assembly of claim 10, wherein said second sheet metal plate has a periphery that is smaller than said lens enclosure rear periphery such that a gap exists which can be filled by a seal.

12. The heatsink assembly of claim 11, wherein said seal is an electronics potting compound.

13. A method of dispersing heat from a printed circuit board having first and second surfaces comprising:
mounting one or more electronic components on said printed circuit board second surface;
arranging a first thermally conductive plate having first and second surfaces and defining recesses configured to receive said one or more electronic components in thermally conductive contact with said printed circuit board second surface.

14. The method of claim 13, wherein a second thermally conductive plate is arranged in thermal communication with said first thermally conductive plate second surface.

15. The method of claim 14, wherein a gasket is arranged intermediate said printed circuit board second surface and said second thermally conductive plate first surface.

16. The method of claim 14, wherein said printed circuit board is arranged within a lens enclosure.

17. The method of claim 15, wherein a seal is arranged intermediate said lens enclosure and the periphery of said second sheet metal plate.
